(19) United States
(12) Patent Application Publication
(10) Pub. No.: US 2026/0231566 A1
(43) Pub. Date: Aug. 6, 2026

(54) ASYMMETRIC-SHAPE SEMICONDUCTOR DEVICE, DEVICE TRANSFER APPARATUS USING THE SAME, AND DISPLAY DEVICE

(71) Applicant: CHUNG ANG University Industry Academic Cooperation Foundation, Seoul (KR)

(72) Inventor: Jaesoo YOO, Seoul (KR)

(73) Assignee: CHUNG ANG University Industry Academic Cooperation Foundation, Seoul (KR)

(21) Appl. No.: 19/240,645

(22) Filed: Jun. 17, 2025

(30) Foreign Application Priority Data
Feb. 5, 2025 (KR) 10-2025-0014716
May 20, 2025 (KR) 10-2025-0065733

(51) Int. Cl. H10H 20/819; H10H 20/825; H10H 29/03

(52) U.S. Cl. CPC H10H 20/819; H10H 20/825; H10H 29/03

(57) ABSTRACT

Provided is a semiconductor device. The semiconductor device includes an epitaxial layer and at least one electrode formed on the epitaxial layer, wherein the epitaxial layer has an asymmetric shape including at least a partial curved section.

### CROSS-REFERENCE TO RELATED APPLICATION

This application is based on and claims priority under 35 U.S.C. § 119 to Korean Patent Application No. 10-2025-0014716, filed on Feb. 5, 2025, and Korean Patent Application No. 10-2025-0065733, filed on May 20, 2025 in the Korean Intellectual Property Office, the disclosures of which are incorporated by reference herein in their entireties.

### BACKGROUND

### 1. Field

The disclosure relates to the field of semiconductor technology, and more particularly, to a semiconductor device having an asymmetric shape. The disclosure also relates to a device transfer apparatus for transferring a semiconductor device to an interposer and a display device including the semiconductor device.

This research has been conducted with the support of Samsung Research Funding & Incubation Center for Future Technology. (Project No. SRFC-IT2201-02)

### 2. Description of the Related Art

Semiconductor devices having micrometer-scale sizes have been widely used. In some embodiments, micro light-emitting diode (LED) chips have been used in display devices. Micro-LED displays are attracting attention as a next-generation display technology based on their advantages such as high display quality, low power consumption, long lifespan, etc. However, one of the biggest factors hindering the commercialization of the micro-LED displays is the high manufacturing cost, and a process of arranging LED chips on pixels and precisely transferring them onto a substrate is a major cost driver. To transfer a plurality of micro-LED chips onto the substrate in a selected pattern, the movements of the micro-LED chips have to be precisely adjusted. Moreover, in the process of transferring the micro-LED chips, all micro-LED chips have to be transferred onto the substrate in the selected pattern.

### SUMMARY

Additional aspects will be set forth in part in the description which follows and, in part, will be apparent from the description, or may be learned by practice of the presented embodiments of the disclosure.

According to an aspect of the disclosure, a semiconductor device includes an epitaxial layer and at least one electrode formed on the epitaxial layer, in which the epitaxial layer has an asymmetric shape including at least a partial curved section.

According to an embodiment, the asymmetric shape may include a shape in which a partial region is removed from a basic shape of a circular shape or an elliptical shape.

According to an embodiment, the asymmetric shape may include a shape including a linear edge of a portion in which a partial region is removed from a basic shape of a circular shape or an elliptical shape.

According to an embodiment, the asymmetric shape may include a shape including a curved edge of a portion in which a partial region is removed from a basic shape of a circular shape or an elliptical shape.

According to an embodiment, the asymmetric shape may be asymmetric in each of a top-down direction, a left-right direction, and a front-back direction.

According to an embodiment, the semiconductor device may include a light-emitting element, the semiconductor device may include a first light-emitting element outputting a first color component, a second light-emitting element outputting a second color component, and a third light-emitting element outputting a third color component, and the first light-emitting element, the second light-emitting element, and the third light-emitting element may have asymmetric shapes of different types.

According to an embodiment, the first light-emitting element, the second light-emitting element, and the third light-emitting element may have asymmetric shapes of types and sizes that do not completely include each other.

According to an embodiment, the semiconductor device may include a light-emitting diode (LED) chip.

According to an embodiment, the semiconductor device may be formed by patterning the epitaxial layer formed on a silicon wafer into the asymmetric shape through photolithography and separating the semiconductor device from the silicon wafer.

According to an embodiment, the semiconductor device has a size of about 3 μm to about 150 μm.

According to an embodiment, the asymmetric shape may include a first linear section formed in a first direction, a second linear section formed in a first direction and parallel with the first linear section, a third linear section connecting an end of the first linear section to an end of the second linear section, and a curved section connecting another end of the first linear section to another end of the second linear section.

According to an embodiment, the curved section may correspond to a chord of a circle or an oval.

According to an embodiment, the asymmetric shape may include a curved section corresponding to a chord of a circle or an oval and a linear section connecting opposite ends of the chord and including at least one bent portion.

According to an embodiment, the asymmetric shape may include a curved section corresponding to a chord of a circle or an oval and at least one concave section and at least one convex section connecting opposite ends of the chord.

According to an embodiment, the semiconductor device may be transferred to a recessed portion of an interposer, and the recessed portion may have a shape that is identical to the asymmetric shape of the semiconductor device and may be formed to have a selected gap with respect to an exterior of the semiconductor device such that the semiconductor device is accommodated.

According to an embodiment, the semiconductor device may be transferred to the interposer through movement by vibration in a fluid.

According to an embodiment, the epitaxial layer may include a plurality of layers including a GaN-based material.

According to another aspect of the disclosure, there is provided a device transfer apparatus. The device transfer apparatus may include a container accommodating an interposer including a plurality of recesses, a plurality of vibration sources configured to generate vibrations and output the vibrations to a fluid in the container, and a processor configured to control output of each of the plurality of vibrations sources. The container may accommodate the fluid and a semiconductor device distributed in the fluid, and the processor may be further configured to output vibrations from at least one of the plurality of vibration sources and transfer the semiconductor device to the plurality of recesses of the interposer. The semiconductor device may include an epitaxial layer and at least one electrode formed on the epitaxial layer, in which the epitaxial layer has an asymmetric shape including at least a partial curved section and each of the plurality of recesses has a shape that is equal to the asymmetric shape of the semiconductor device and is formed to have a selected gap with respect to an exterior of the semiconductor device such that the semiconductor device may be accommodated.

According to another aspect of the disclosure, there is provided a display device. The display device may include a display panel including a plurality of first light-emitting elements outputting a first color component, a plurality of second light-emitting elements outputting a second color component, and a plurality of third light-emitting elements outputting a third color component and a driving circuit configured to drive the display panel. Each of the plurality of first light-emitting elements, the plurality of second light-emitting elements, and the plurality of third light-emitting elements may include an epitaxial layer and at least one electrode formed on the epitaxial layer, in which the epitaxial layer has an asymmetric shape including at least a partial curved section, and the first light-emitting element, the second light-emitting element, and the third light-emitting element have asymmetric shapes of different types.

According to an embodiment, the first light-emitting element, the second light-emitting element, and the third light-emitting element may have asymmetric shapes of types and sizes that do not completely include each other.

### BRIEF DESCRIPTION OF THE DRAWINGS

The above and other aspects, features, and advantages of certain embodiments of the disclosure will be more apparent from the following description taken in conjunction with the accompanying drawings, in which:

The disclosure may be easily understood by a combination of the following detailed description and the accompanying drawings, and reference numerals may refer to structural elements.

FIG. 1 is a cross-sectional view showing a structure of a semiconductor device, according to an embodiment;

FIG. 2 is a top view of a semiconductor device, according to an embodiment;

FIG. 3 shows a structure of an epitaxial layer according to an embodiment;

FIG. 4 shows a structure of an epitaxial layer according to an embodiment;

FIG. 5 shows a layer structure of a semiconductor device, according to an embodiment;

FIG. 6 shows a process of manufacturing a semiconductor device and transferring the semiconductor device to an interposer, according to an embodiment;

FIGS. 7A, 7B, and 7C show a semiconductor device production process of manufacturing a semiconductor device according to an embodiment;

FIG. 8 shows a first asymmetric shape of a semiconductor device, according to an embodiment;

FIG. 9 shows a second asymmetric shape of a semiconductor device, according to an embodiment;

FIG. 10 shows a second asymmetric shape of a semiconductor device and an asymmetric shape of a recessed portion of an interposer, according to an embodiment;

FIG. 11 shows a third asymmetric shape of a semiconductor device, according to an embodiment;

FIG. 12 shows a fourth asymmetric shape of a semiconductor device, according to an embodiment;

FIG. 13 shows a fifth asymmetric shape of a semiconductor device, according to an embodiment;

FIG. 14A shows a recessed portion of an interposer in which light-emitting elements are to be arranged, according to an embodiment;

FIG. 14B shows an arrangement of a recessed portion of an interposer according to an embodiment;

FIG. 15A shows a sixth asymmetric shape of a semiconductor device, according to an embodiment;

FIG. 15B shows deformation of a sixth asymmetric shape of a semiconductor device, according to an embodiment;

FIG. 16 shows a seventh asymmetric shape of a semiconductor device, according to an embodiment;

FIG. 17 shows an eighth asymmetric shape of a semiconductor device, according to an embodiment;

FIG. 18 shows electrodes of light-emitting elements according to an embodiment;

FIG. 19 shows electrode arrangement of a semiconductor device, according to an embodiment;

FIG. 20 shows electrode arrangement of a semiconductor device, according to an embodiment;

FIG. 21 shows a structure of a device transfer apparatus according to an embodiment; and

FIG. 22 shows a display device according to an embodiment.

### DETAILED DESCRIPTION

Reference will now be made in detail to embodiments, examples of which are illustrated in the accompanying drawings, wherein like reference numerals refer to like elements throughout. In this regard, the current embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

The principles of the embodiments of the disclosure will be described and the embodiments will be disclosed to clarify the scope of the claims and to allow those of ordinary skill in the art to carry out the embodiments of the disclosure. The disclosed embodiments may be implemented in various forms.

Throughout the disclosure, identical reference numerals refer to identical components. The disclosure does not describe all elements of the embodiments, and general matters in the technical field belonging to the embodiments of the disclosure or redundant matters between the embodiments will be omitted. The term ‘part’ (portion) used herein may be implemented as software or hardware, and depending on the embodiments, a plurality of ‘parts’ may be implemented as one unit (element), or a single ‘part’ may include a plurality of elements. Hereinafter, the embodiments of the disclosure and the operating principles of the embodiments will be described with reference to the attached drawings.

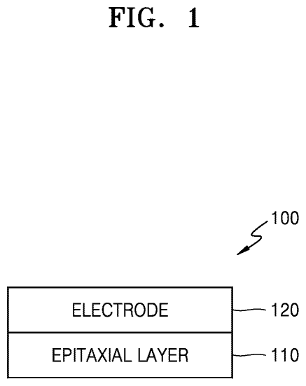

FIG. 1 is a cross-sectional view showing a structure of a semiconductor device, according to an embodiment.

According to an embodiment, a semiconductor device 100 may include an epitaxial layer 110 and an electrode 120.

The epitaxial layer 110 may be a high-quality monocrystal thin film formed on a crystalline substrate. The epitaxial layer 110 may grow to have a crystalline structure that is the same as or similar to that of a substrate, and form a structure aligned in atomic units while maintaining a direction of crystals of the substrate.

In an embodiment, the epitaxial layer 110 may include a light-emitting layer of an LED chip and may be formed of III-V group compound semiconductor materials such as gallium nitride (GaN), aluminum gallium nitride (AlGaN), indium gallium nitride (InGaN), etc. Such materials may control emission wavelengths according to their composition ratios and thus may implement light emission in various colors such as blue, green, red, etc.

The epitaxial layer 110 may be formed on a substrate such as sapphire (Al2O3), silicon (Si), or gallium arsenide (GaAs) through a growth process such as metal organic chemical vapor deposition (MOCVD), hybride vapor phase epitaxy (HVPE), etc. In epitaxial growth, a buffer layer may be formed first to alleviate mismatch between the substrate and a lattice.

The epitaxial layer 110 electronic device according to an embodiment may be formed on a silicon wafer. Thereafter, the epitaxial layer 110 may be patterned in an asymmetric shape and may be separated from the silicon wafer using a lift-off process. The epitaxial layer 110 may be patterned using a photolithography process.

The electrode 120 may be formed on the epitaxial layer 110. The electrode 120 may be electrically connected to the epitaxial layer 110 to receive current from an external power source and inject electric charges to the epitaxial layer 110. The electrode 120 may include a p-type electrode and an n-type electrode. In other words, the electrode 120 may include an anode and a cathode.

The electrode 120 may also include substances such as Ti, Al, Au, etc. The electrode 120 may also include a transparent electrode or a reflective electrode. The transparent electrode may use an indium tin oxide (ITO). The reflective electrode may use gold (Au), silver (Ag), aluminum (Al), etc. According to an embodiment, the electrode 120 may further include an interface layer or a buffer layer to reduce a contact resistance.

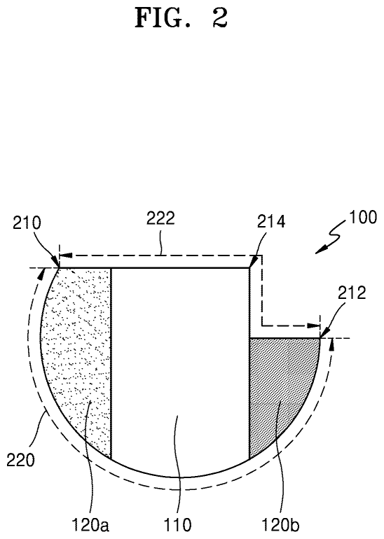

FIG. 2 is a top view of a semiconductor device, according to an embodiment.

According to an embodiment, the semiconductor device 100 may have an asymmetric shape. According to an embodiment, the semiconductor device 100 may have a plate shape. The semiconductor device 100 may have a structure that is relatively large in length and width in a planar direction and thin in a thickness direction.

The semiconductor device 100 may include a main reference plane referred to as a main plane. The main plane may be defined based on a top surface and a bottom surface of a device, and may be used as a functional surface on which the electrode 120 is formed or which contacts an external circuit. The main plane may be a plane serving as a reference for directivity alignment or pattern alignment of chips based on a direction perpendicular to a stacking direction of the device.

The thickness direction of the semiconductor device 100 may be perpendicular to the main plane. As the semiconductor device 100 is arranged to contact a surface of the substrate along the main plane, connection precision and mechanical adhesion of the electrode 120 may be improved.

The asymmetric shape may refer to a shape in which an edge of the main plane is asymmetric. When viewed from the top surface or the bottom surface of the semiconductor device 100, the edge of the semiconductor device 100 has an asymmetric shape. The semiconductor device 100 may have an asymmetric shape in a left-right direction, a top-bottom direction, and a front-back direction when the main plane is viewed.

The semiconductor device 100 according to an embodiment may be designed to have an asymmetric shape without rotational symmetry, while having a plate shape. This may mean that even in case that the semiconductor device 100 rotates at a certain angle in a 360-degree direction, the same shape is not repeated.

In some embodiments, in case that the semiconductor device 100 includes an unbalanced outer shape or a structure protruding to a side rather than a symmetric structure in which the same shape is repeated in rotation, such as an equilateral triangle, a square, a circle, etc., the device may maintain clear directivity in spite of rotating at any angle. Such a structure may cause the chip to match the pattern of the substrate in a specific direction and enable accurate position matching of an electrode, in a self-assembling process or a transferring process.

Thus, in an embodiment, the semiconductor device 100 may have a plate-shape asymmetric structure in which there is no symmetric surface throughout the entire 360-degree rotation area, thereby preventing electrical misalignment and improving alignment reliability. According to an embodiment, as the semiconductor device 100 may have an asymmetric shape, in arrangement of the semiconductor device 100 in the interposer, a direction and arrangement may be automatically controlled without additional process and force (e.g., a magnetic force, an electrostatic force, a Van der Waals force, etc.) for adjusting the position or direction of the semiconductor device 100.

The asymmetric shape may have at least a partial curved section 220. The curved section 220 may be formed by being etched into a curve using a photolithography process. According to an embodiment, the curved section 220 may correspond to a chord of a circle or an oval. The curved section 220 may include one continuous curved section or may include a plurality of curved sections with straight sections inserted in the middle thereof.

The semiconductor device 100 may include a straight section 222 connected to the curved section 220. The straight section 222 may connect opposite ends 210 and 212 of the curved section 220. In some embodiments, the straight section 222 may connect the end 210 of the curved section 220 to the other end 212 of the curved section 220. The straight section 222 may include one or more straight lines. In some embodiments, the straight section 222 may include a plurality of straight lines including a bent point 214.

The semiconductor device 100 may include at least one electrodes 120a and 120b on the epitaxial layer 110. The electrodes 120a and 120b may be arranged on a surface or opposite surfaces of the epitaxial layer 110. According to an embodiment, the semiconductor device 100 may have an asymmetric shape such that the surface on which the electrodes 120a and 120b are arranged may be transferred to the interposer in a selected direction. As the semiconductor device 100 has asymmetry in the front-back direction, there is no possibility that the semiconductor device 100 is transferred to a recessed portion of the interposer while being flipped over.

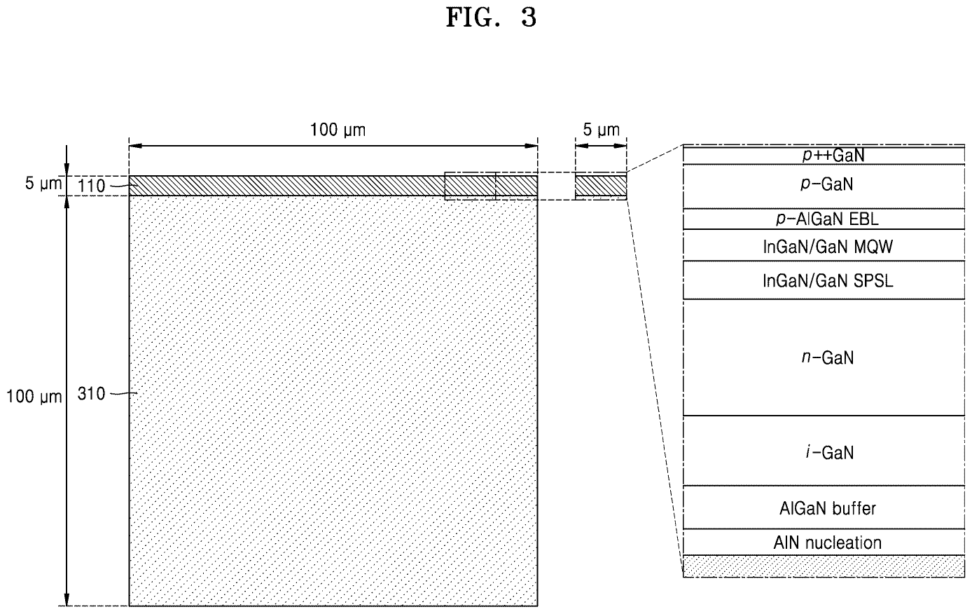

FIG. 3 shows a structure of an epitaxial layer according to an embodiment.

According to an embodiment, the epitaxial layer 110 may grow on a substrate 310. According to an embodiment, a substrate 310 may correspond to a silicon wafer or a sapphire substrate. In a semiconductor device manufacturing process, after the substrate 310 (e.g., sapphire, silicon, a GaAs wafer, etc.) having a thickness of 400 μm to 500 μm is cleaned, the epitaxial layer 110 may grow thereon using MOCVD or HVPE. The wafer on which the epitaxial layer 110 grows may be referred to as an epi-wafer. In some embodiments, the epi-wafer may correspond to an epi-wafer in which the epitaxial layer 110 grows on sapphire or an epi-wafer in which the epitaxial layer 110 grows on a silicon wafer. Metal for an electrode may be deposited through a metal process on a top portion of the epi-wafer, and an insulating layer may be formed to form a p-electrode and an n-electrode. The individual semiconductor device 100 (e.g., an LED chip) may be arranged on top of the epi-wafer on which the electrodes are formed.

For a mini-LED having a chip size of about 100 μm, in the semiconductor device manufacturing process, the sapphire substrate on which the epitaxial layer 110 grows may be grinded to a thickness less than about 100 μm and then marked with a laser and applied with a force so as to be broken, thereby obtaining an individual chip. In case that the individual chip is obtained, the obtained chip may be arranged on the interposer or a driving circuit board.

For a chip size less than about 40 μm, a chip thickness is about 5 μm to about 8 μm, such that in the semiconductor device manufacturing process, the chip may be etched to a thickness of about 8 μm through dry etching and removed from the silicon substrate through wet etching, thereby arranging the chip on the driving circuit or the interposer.

According to an embodiment, the epitaxial layer 110 may include an AIN nucleation layer, an AlGaN buffer layer, an i-GaN layer, an n-GaN layer, an InGaN/GaN short-period super lattice (SPSL) layer, an InGaN/GaN MQW layer, a p-AlGaN electron blocking layer (EBL), a p-GaN layer, a p++ GaN layer, etc., from bottom. The epitaxial layer 110 may be separated from the substrate 310 after etching of the semiconductor device 100 is finished.

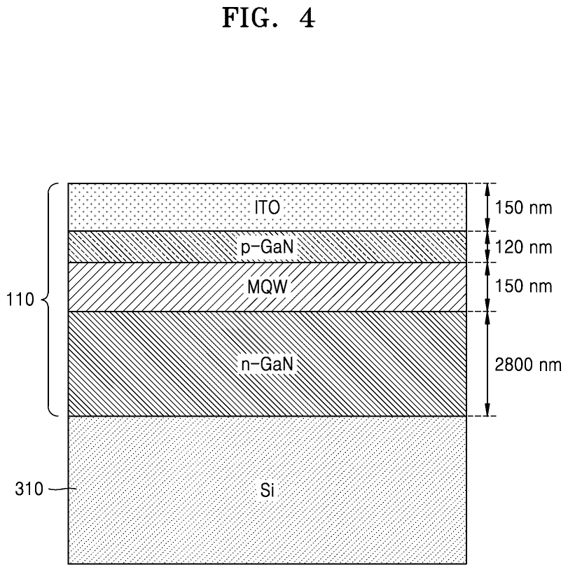

FIG. 4 shows a structure of an epitaxial layer according to an embodiment.

According to an embodiment, the epitaxial layer 110 may grow on the substrate 310. According to an embodiment, the substrate 310 may correspond to a silicon wafer. The epitaxial layer 110 may be formed to a thickness of, e.g., about 1 μm to about 10 μm.

According to an embodiment, the epitaxial layer 110 may include an n-GaN layer, a multiple quantum well (MQW) layer, a p-GaN layer, and an ITO layer from bottom. According to an embodiment, n-GaN layer may be formed to a thickness of about 2800 nm, the MQW layer may be formed to a thickness of about 150 nm, the p-GaN layer may be formed to a thickness of about 120 nm, and the ITO layer may be formed to a thickness of about 150 nm. A thickness of each layer in an example shown in FIG. 4 is illustrative, and the thickness of the epitaxial layer 110 and the thickness of each layer may be determined variously. The MQW layer may include, e.g., GaAs and AlGaAs. The MQW layer may also include, e.g., InGaN and GaN.

A hole depth including ITO may correspond to about 1.4 μm. The electrode 120 may be formed to have a structure in which a Ti layer, an Al layer, a Ti layer, and an Au layer are stacked. The Ti layer, the Al layer, the Ti layer, and the Au layer may be respectively formed to have thicknesses of about 20 nm, about 200 nm, about 20 nm, and about 200 nm.

The structure of the epitaxial layer 110 of FIG. 4 may be used in a micro LED chip.

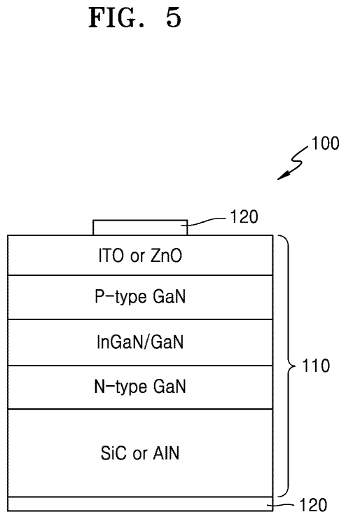

FIG. 5 shows a layer structure of a semiconductor device, according to an embodiment.

According to an embodiment, the semiconductor device 100 may include the epitaxial layer 110 and the electrodes 120 arranged on opposite surfaces of the epitaxial layer 110.

The semiconductor device 100 of FIG. 5 may correspond to a vertical chip having opposite surfaces on which the electrodes 120 are arranged. LED chips may be divided into a flip chip and a vertical chip, and electrodes may be arranged on a top surface and a bottom surface of the flip chip. A p-electrode may be arranged on, e.g., a top surface of the vertical chip and an n-electrode may be arranged on, e.g., a bottom surface of the vertical chip. According to an embodiment, the semiconductor device 100 in the form of a vertical chip may be manufactured in an asymmetric shape, thereby transferring the semiconductor device 100 to the recessed portion of the interposer in a specific direction.

The epitaxial layer 110 may include a substrate, a bottom confinement layer, an active region, a top confinement layer, and a current spreading layer. The substrate may correspond to an SiC layer or an AlN layer. The bottom confinement layer may correspond to an n-type GaN layer. The active region may correspond to an InGaN/GaN layer. The top confinement layer may correspond to a p-type GaN layer. The current spreading layer may correspond to an ITO layer or a ZnO layer. The bottom confinement layer, the active region, and the top confinement layer may constitute a double hetero-junction structure.

The electrode 120 may include a Ti layer, a W layer, and an Au layer.

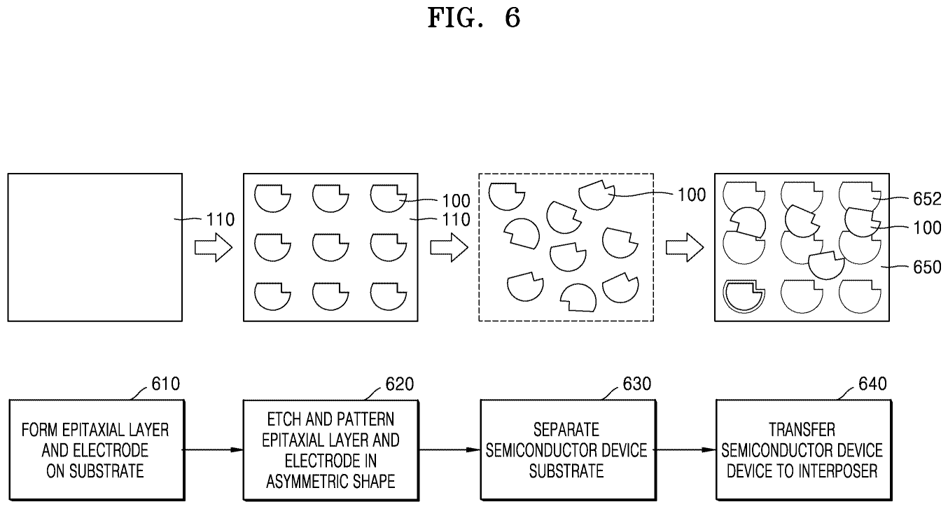

FIG. 6 shows a process of manufacturing a semiconductor device and transferring a semiconductor device to an interposer, according to an embodiment.

According to an embodiment, in a semiconductor device production process, the epitaxial layer 110 and the electrode 120 may be formed on a silicon wafer, and the semiconductor device 100 may be molded in an asymmetric shape through etching using photolithography. Thereafter, a device transfer apparatus may transfer the semiconductor device 100 to an interposer 650.

Referring to FIG. 6, in operation 610, the semiconductor device production process may include forming the epitaxial layer 110 and the electrode 120 on a substrate. The substrate may correspond to a silicon wafer.

When growth of the epitaxial layer 110 is completed, the semiconductor device production process may include molding the epitaxial layer 110 and the electrode 120 in a predefined asymmetric shape through etching using photolithography, in operation 620. The semiconductor device production process may include patterning the epitaxial layer 110 in a shape of the semiconductor device 100 to pattern the plurality of semiconductor devices 100.

Next, the semiconductor device production process may include separating the semiconductor device 100 from the substrate through a lift-off process, in operation 630. The semiconductor device 100 separated from the substrate may have a shape of an individual chip.

Next, the device transfer apparatus may transfer the semiconductor device 100 to the interposer 650 in operation 640. The interposer 650 may include a recessed portion 652 having a selected pattern capable of receiving the semiconductor device 100. The recessed portion 652 may have a shape corresponding to the asymmetric shape of the semiconductor device 100. The recessed portion 652 may be formed to have a shape having a selected gap with respect to the size of the semiconductor device 100. In some embodiments, the recessed portion 652 may have an asymmetric shape that is the same as the semiconductor device 100 and may be formed to have a size greater than the size of the semiconductor device 100 by about 3% to about 13%, which may be a key design variable that may be adjusted for accurate and fast transfer. The recessed portion 652 may have a depth that is equal to or lower than a depth of the semiconductor device 100. The interposer 650 may be used to transport the semiconductor device 100 and transfer the semiconductor device 100 to another substrate.

According to an embodiment, the device transfer apparatus may arrange the interposer 650 and the semiconductor device 100 in a container containing a fluid and transmit vibration energy to the container. As the semiconductor device 100 moves in the fluid by the vibration energy, the semiconductor device 100 may be self-assembled.

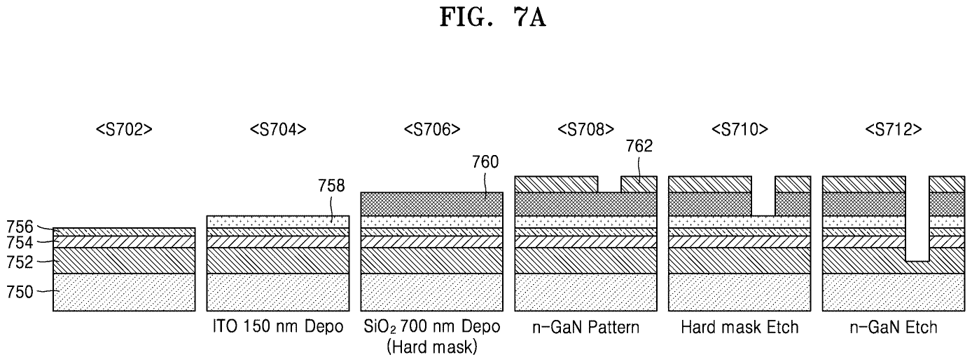

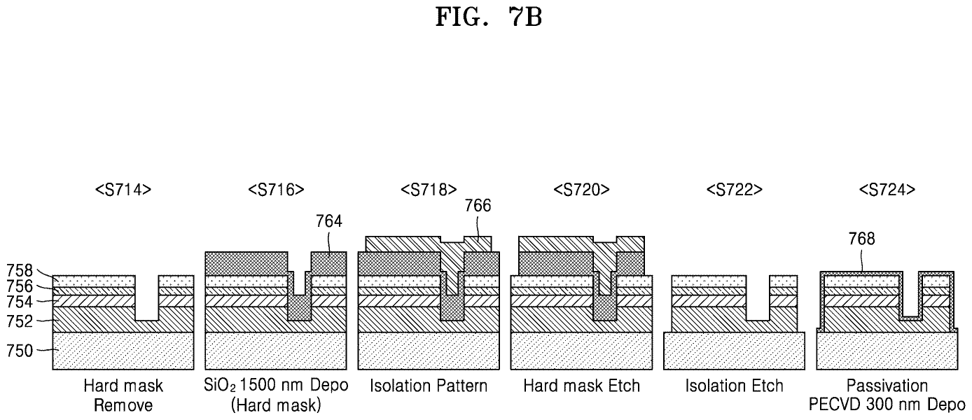

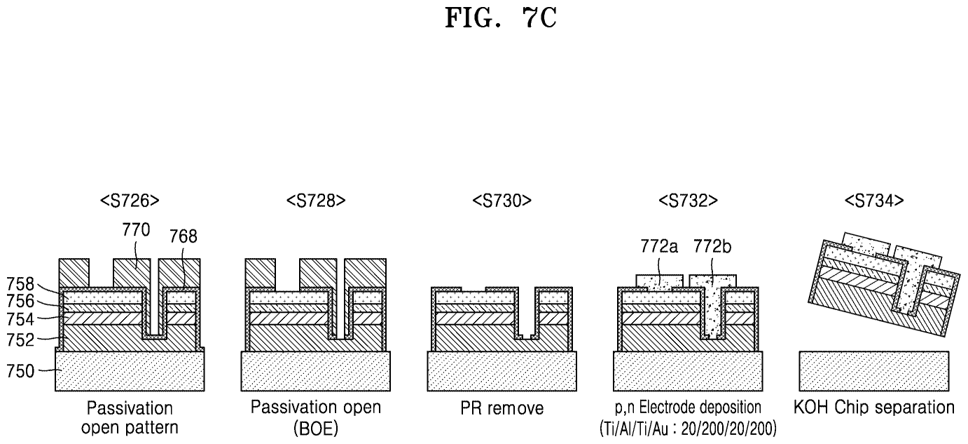

FIGS. 7A, 7B, and 7C show a semiconductor device production process of manufacturing a semiconductor device according to an embodiment.

The semiconductor device manufacturing process of FIGS. 7A, 7B, and 7C may correspond to a process of manufacturing the semiconductor device 100 with the structure of the epitaxial layer 110 of FIG. 4. The epitaxial layer 110 of the embodiment described with reference to FIGS. 3 and 5 may also be manufactured similarly with a manner described in FIG. 7. The semiconductor device manufacturing process of FIGS. 7A, 7B, and 7C may correspond to a process for manufacturing an LED flip chip.

Referring to FIG. 7A, the semiconductor device manufacturing process may include growing an n-GaN layer 752, an MQW layer 754, and a p-GaN layer on a silicon wafer 750, in operation S702. According to an embodiment, the silicon wafer 750 may correspond to a monocrystal silicon wafer. The semiconductor device production process may grow the epitaxial layer 110 using a growth process such as MOCVD, HVPE, etc. According to an embodiment, an undoped-GaN layer may be further included between the silicon wafer 750 and the n-GaN layer 752.

Next, the semiconductor device manufacturing process may grow an ITO layer 758 in operation S704. The ITO layer 758 may correspond to a current spreading layer. The ITO layer 758 may be deposited on a p-GaN layer 756. The ITO layer 758 may grow to have a thickness of about 150 nm. The epitaxial layer 110 may improve ohmic contact characteristics and current injection efficiency by introducing the current spreading layer. According to an embodiment, the ITO layer 758 may be deposited through an RF sputter. According to an embodiment, a surface resistance of the deposited ITO layer 758 may be about 16.7 Ω/cm².

Next, the semiconductor device manufacturing process may include generating a passivation layer 760 on the ITO layer 758 in operation S706. The first passivation layer 760 may be formed by depositing, for example, SiO₂ or Si₃N₄. The first passivation layer 760 may serve as a hard mask. In some embodiments, to form a hard mask for etching GaN, silica (SiO₂) may be deposited on the ITO layer 758 using PECVD equipment. The first passivation layer 760 may be deposited to a thickness of, for example, about 700 nm.

The semiconductor device manufacturing process may include forming a first photoresist 762 on the first passivation layer 760 in operation S708. The semiconductor device manufacturing process may include applying a photoresist material (e.g., AZ5214, Merk) using a spin coating process (e.g., 3500 RPM 40 sec). Thereafter, the semiconductor device manufacturing process may include dropping a photoresist material on the center of the substrate and then rotating the substrate at high speed to uniformly distribute the photoresist material over the entire substrate. The semiconductor device manufacturing process may include a soft bake process to stabilize the applied photoresist material. The semiconductor device production process may heat the substrate to a specific temperature (e.g., about 90° C. to about 110° C.) to remove a residual solvent in the photoresist material and improve adhesion. The soft bake process may be performed, for example, at 95° C. for 1 minute and 30 seconds. After the soft bake process is completed, the semiconductor device manufacturing process may etch a first photoresist layer 762 into a selected pattern using photolithography. In some embodiments, the semiconductor device production process may include exposing the first photoresist layer 762 to light with the selected pattern by using a mask. The semiconductor device manufacturing process may include exposing the substrate on which the first photoresist layer 762 is arranged, by using a contact aligner. Thereafter, the semiconductor device production process may include removing a partial region from the first photoresist layer 762 having been exposed to light, by using a developer (e.g., AZ300MIF, Merck). The semiconductor device manufacturing process may improve heat resistance and adhesion of the first photoresist layer 762 by hard baking the first photoresist layer 762 having been developed using the developer.

The semiconductor device manufacturing process may include etching the first passivation layer 760 into a selected pattern in operation S710. According to an embodiment, the semiconductor device production process may include performing a dry etching process to remove the exposed first passivation layer 760 on which the first photoresist layer 762 is not formed. The semiconductor device production process may include etching the first passivation layer 760 formed of silica by using fluorine-based plasma. In some embodiments, CF₄, CHF₃, SF₆, or a combination thereof may be supplied in a plasma state, and the first passivation layer 760 may be etched anisotropically or isotropically by ions and radicals. Etching conditions may be controlled according to selectivity and pattern resolution.

The semiconductor device manufacturing process may include etching at least one GaN layers 752, 754, and 756 according to a pattern formed by the first photoresist layer 762 and the first passivation layer 760, in operation S712. According to an embodiment, the semiconductor device manufacturing process may include etching the GaN layers 752, 754, and 756 by using an RIE-ICP plasma etcher. According to an embodiment, the semiconductor device manufacturing process may include etching the first passivation layer 760 formed of silica by using fluorine-based plasma and etching the ITO layer 758 and the GaN layers 752, 754, and 756 by using chlorine-based plasma. Through this process, etching to a target depth may be possible due to a difference in etch selectivity between the first passivation layer 760 formed of silica, and the ITO layer 758 and the GaN layers 752, 754, and 756.

Referring to FIG. 7B, the next process will be described. The semiconductor device production process may include removing the first passivation layer 760 corresponding to the hard mask and the first photoresist layer 762, in operation S714. The first photoresist layer 762 may be removed using a stripping process. The first passivation layer 760 may be removed using a buffer oxide etchant (BOE).

The semiconductor device production process may include growing a second passivation layer 764 on the ITO layer 758, in operation S716. According to an embodiment, the second passivation layer 764 may be arranged at intervals of about 1500 nm. The second passivation layer 764 may serve as a hard mask.

The semiconductor device production process may include forming a second photoresist layer 766 on the second passivation layer 764, in operation S718. According to an embodiment, the second photoresist layer 766 may grow to correspond to the asymmetric shape of the semiconductor device 100. In some embodiments, the second photoresist layer 766 may be developed after exposed to light in a pattern corresponding to the asymmetric shape of the semiconductor device 100 by using a mask of a pattern corresponding to the asymmetric shape of the semiconductor device 100.

The semiconductor device production process may include etching the second passivation layer 764 according to the pattern of the second photoresist layer 766, in operation S720.

The semiconductor device production process may include etching the ITO layer 758 and the GaN layers 752, 754, and 756 according to the pattern of the second passivation layer 764, in operation S722.

The semiconductor device production process may include forming a third passivation layer 768 on the ITO layer 758 and the silicon wafer 750, in operation S724. The third passivation layer 768 may be formed using a PECVD process. The third passivation layer 768 may be formed to have a thickness of about 300 nm.

Next, the next process will be described using FIG. 7C.

Referring to FIG. 7C, the semiconductor device production process may include forming a third photoresist layer 770 on the third passivation layer 768, in operation S726. The third photoresist layer 770 may be formed to correspond to a contact pattern of the electrode 120.

The semiconductor device production process may include etching the third passivation layer 768 according to the pattern of the third photoresist layer 770, in operation S728. According to an embodiment, by etching the third passivation layer 768, a partial region of the ITO layer 758 and a partial region of the nGaN layer 752 may be exposed.

The semiconductor device production process may include removing the third photoresist layer 770 in operation S730.

The semiconductor device production process may include forming at least one electrodes 772a and 772b on the third passivation layer 768, in operation S732. The semiconductor device production process may include depositing an electrode material on the third passivation layer 768 and an exposed layer. The semiconductor device production process may include depositing an electrode material by using, for example, sputtering, evaporation, atomic layer deposition (ALD), chemical vapor deposition (CVD), etc. The electrode material may include, for example, Ti, Al, Ni, Au, Ag, ITO, etc. The semiconductor device production process may include removing a portion other than a required region from a deposited electrode layer. In some embodiments, the semiconductor device production process may include forming an electrode pattern using photolithography. According to an embodiment, the electrodes 772a and 772b may include an anode 772a and a cathode 772b. According to an embodiment, the electrodes 772a and 772b may be formed to have a structure in which a Ti layer, an Al layer, a Ti layer, and an Au layer are stacked. The Ti layer, the Al layer, the Ti layer, and the Au layer may be respectively formed to have thicknesses of about 20 nm, about 200 nm, about 20 nm, and about 200 nm.

Next, the semiconductor device production process may include separating the semiconductor device 100 from the silicon wafer 750, in operation S734. According to an embodiment, the semiconductor device 100 may be separated from the silicon wafer 750 through a wet etching process using a potassium hydroxide (KOH) solution. As an edge of the semiconductor device 100 is etched in an asymmetric shape, the semiconductor device 100 may be separated from the silicon wafer 750, thus having a form of a chip formed independently of another semiconductor device 100.

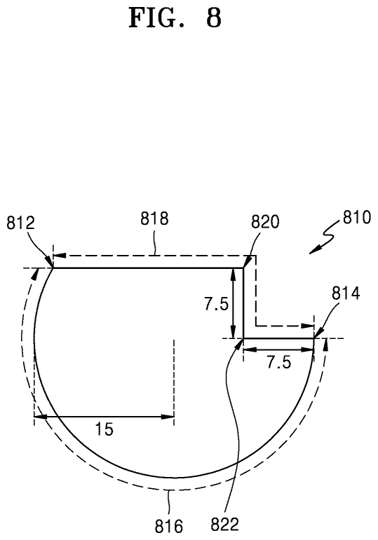

FIG. 8 shows a first asymmetric shape of a semiconductor device, according to an embodiment.

According to an embodiment, the semiconductor device 100 may have a first asymmetric shape 810. The first asymmetric shape 810 may include a curved section 816 between a first point 812 and a second point 814 and a linear section 818 between the first point 812 and the second point 814. The curved section 816 may correspond to a chord of a circle or an oval. The linear section 818 may include at least one bent points 820 and 822 and a plurality of straight lines.

According to an embodiment, the curved section 816 may correspond to a chord of a circle having a radius of about 10 μm to about 50 μm. In some embodiments, the curved section 816 may have a radius of about 15 μm. According to an embodiment, two straight lines may perpendicularly meet each other at a third point 820 and a fourth point 822. According to an embodiment, a length between the third point 820 and the fourth point 822 and a length between fourth point 822 and the second point 814 may correspond to ½ of a radius of a circle corresponding to the curved section 816. In some embodiments, the length between the third point 820 and the fourth point 822 and the length between the fourth point 822 and the second point 814 may correspond to about 7.5 μm.

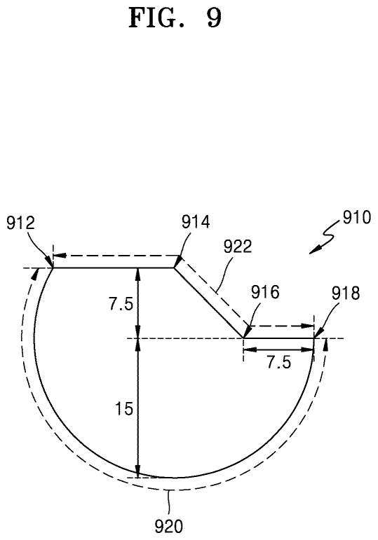

FIG. 9 shows a second asymmetric shape of a semiconductor device, according to an embodiment.

According to an embodiment, the semiconductor device 100 may have a second asymmetric shape 910. The second asymmetric shape 910 may include a curved section 920 between an 11th point 912 and a 12th point 918 and a linear section 922 between the 11th point 912 and the 12th point 918. The curved section 920 may correspond to a chord of a circle or an oval. The linear section 922 may include at least one bent points 914 and 916 and a plurality of straight lines.

According to an embodiment, the curved section 920 may correspond to a chord of a circle having a radius of about 10 μm to about 50 μm. In some embodiments, the curved section 920 may have a radius of about 15 μm. According to an embodiment, two straight lines may meet each other at an obtuse angle at a 13th point 914 and a 14th point 916. According to an embodiment, a length between the 14th point 916 and the 12th point 918 may correspond to ½ of the radius of the circle corresponding to the curved section 920. In some embodiments, the length between the 14th point 916 and the 12th point 918 may correspond to about 7.5 μm. A straight line between the 11th point 912 and the 13th point 914 and a straight line between the 14th point 916 and the 12th point 918 may be parallel to each other, and may have, therebetween, a distance of ½ of the radius of the circle corresponding to the curved section 920. In some embodiments, the distance between the straight line between the 11th point 912 and the 13th point 914 and the straight line between the 14th point 916 and the 12th point 918 may correspond to about 7.5 μm.

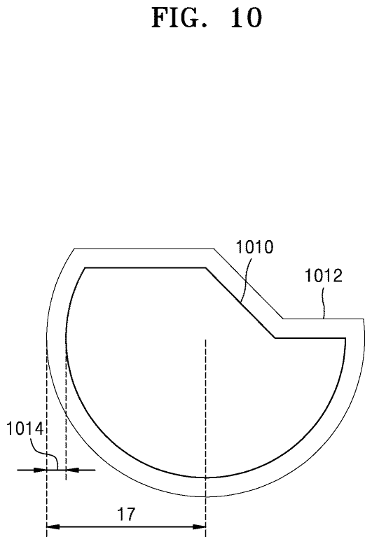

FIG. 10 shows a second asymmetric shape of a semiconductor device and an asymmetric shape of a recessed portion of an interposer, according to an embodiment.

According to an embodiment, the recessed portion of the interposer may have a shape corresponding to the asymmetric shape of the semiconductor device 100. The recessed portion may be formed to have a gap 1014 of a selected length with respect to the size of the semiconductor device 100 to allow the semiconductor device 100 to be inserted. A tolerance of the gap of the recessed portion may differ with electrode arrangement. The tolerance of the gap of the recessed portion may be optimized for fast and accurate transfer.

According to an embodiment, the semiconductor device 100 may have the second asymmetric shape 1010, and the recessed portion of the interposer may have a shape corresponding to the second asymmetric shape 1010 and may have a recessed portion asymmetric shape 1012 having the gap 1014 of the selected length. According to an embodiment, the length of the gap 1014 may be about 5% to about 10% of a diameter of the semiconductor device 100. In some embodiments, the second asymmetric shape 1010 may have a diameter of about 30 μm, and the recessed portion asymmetric shape 1012 may have a diameter of about 34 μm. In this case, the gap 1014 may correspond to 2 μm.

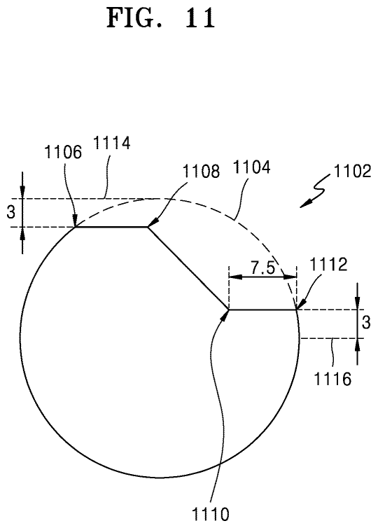

FIG. 11 shows a third asymmetric shape of a semiconductor device, according to an embodiment.

A third asymmetric shape 1102 of the semiconductor device electronic device according to an embodiment may be defined as a shape in which a partial region of a first circle 1104 corresponding to a basic shape is cut. According to an embodiment, the first circle 1104 may correspond to a radius of about 15 μm. The third asymmetric shape 1102 may include a curved section and a linear section like the second asymmetric shape 910.

A straight line between a 21st point 1106 and a 22nd point 1108 may be defined as a parallel line having a selected distance from a tangent 1114 of the first circle 1104. In some embodiments, the straight line between the 21st point 1106 and the 22nd point 1108 may be a parallel line having a distance of 3 μm from the tangent 1114 of the first circle 1104.

A straight line between a 23rd point 1110 and a 24th point 1112 may be defined to be parallel to the straight line between the 21st point 1106 and the 22nd point 1108. The straight line between the 23rd point 1110 and the 24th point 1112 may be defined to be parallel to a diameter line 1116 of the first circle 1104 and to have a selected distance therefrom. In some embodiments, the straight line between the 23rd point 1110 and the 24th point 1112 may have a distance of 3 μm from the diameter line 1116 of the first circle 1104. The straight line between the 23rd point 1110 and the 24th point 1112 may have a length of, for example, about 7.5 μm.

At the 22nd point 1108 and the 23rd point 1110, two straight lines may meet each other at an obtuse angle.

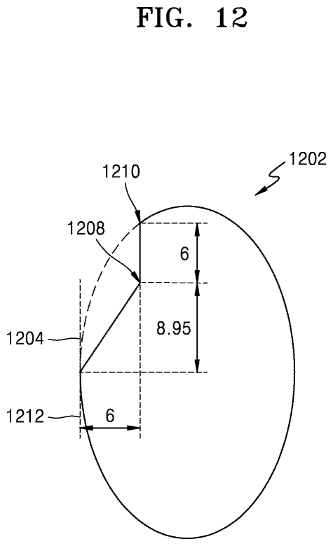

FIG. 12 shows a fourth asymmetric shape of a semiconductor device, according to an embodiment.

According to an embodiment, a fourth asymmetric shape 1202 of the semiconductor device 100 may have a form in which a partial region is removed from a first oval 1204 corresponding to a basic shape. In some embodiments, the fourth asymmetric shape 1202 may be based on the first oval 1204 having a major axis of 35 μm and a minor axis of about 25 μm.

The fourth asymmetric shape 1202 may include a curved section between a 31st point 1206 and a 33rd point 1210 and a linear section between the 31st point 1206 and the 33rd point 1210. The linear section may include two straight lines meeting each other at a 32nd point 1208. A straight line between the 32nd point 1208 and the 33rd point 1210 may be parallel to a major axis. The straight line between the 32nd point 1208 and the 33rd point 1210 may be parallel to a tangent 1212 parallel to the major axis and may have a selected distance from the tangent 1212. In some embodiments, the straight line between the 32nd point 1208 and the 33rd point 1210 may have a distance of about 6 μm from the tangent 1212. The straight line between the 32nd point 1208 and the 33rd point 1210 may have a length of about 6 μm.

The 31st point 1206 may correspond to an end of the minor axis of the first oval 1204. The 32nd point 1208 may be located at a selected distance from the minor axis of the first oval 1204. In some embodiments, the 32nd point 1208 may be located at a distance of 8.95 μm from the minor axis of the first oval 1204.

At the 32nd point 1208, two straight lines meet each other at an obtuse angle.

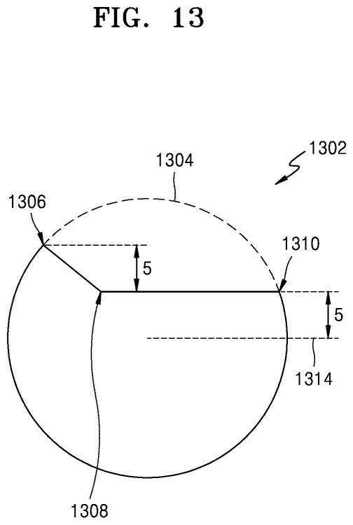

FIG. 13 shows a fifth asymmetric shape of a semiconductor device, according to an embodiment.

According to an embodiment, a fifth asymmetric shape 1302 of the semiconductor device 100 may be defined as a shape in which a partial region is removed from a second oval 1304. The second oval 1304 may correspond to, for example, a circle having a diameter of about 30 μm. The fifth asymmetric shape 1302 may include a curved section between a 41st point 1306 and a 43rd point 1310 and a linear section between the 41st point 1306 and the 43rd point 1310. The linear section may include two straight lines meeting each other at a 42nd point 1308. A length of the straight line between the 41st point 1306 and the 42nd point 1308 and a length of the straight line between the 42nd point 1308 and the 43rd point 1310 may be different from each other.

The straight line between the 42nd point 1308 and the 43rd point 1310 may have a selected distance from a diameter 1314 parallel to the straight line. In some embodiments, the straight line between the 42nd point 1308 and the 43rd point 1310 may have a distance of about 5 μm from the diameter 1314 parallel to the straight line. The 41st point 1306 may have a selected distance from the straight line between the 42nd point 1308 and the 43rd point 1310. In some embodiments, the 41st point 1306 may have a distance of about 5 μm from the straight line between the 42nd point 1308 and the 43rd point 1310.

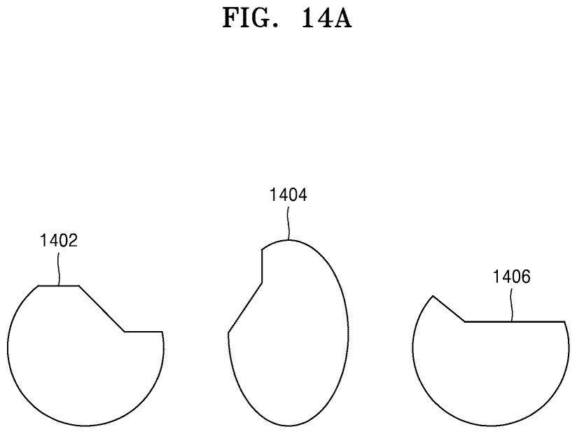

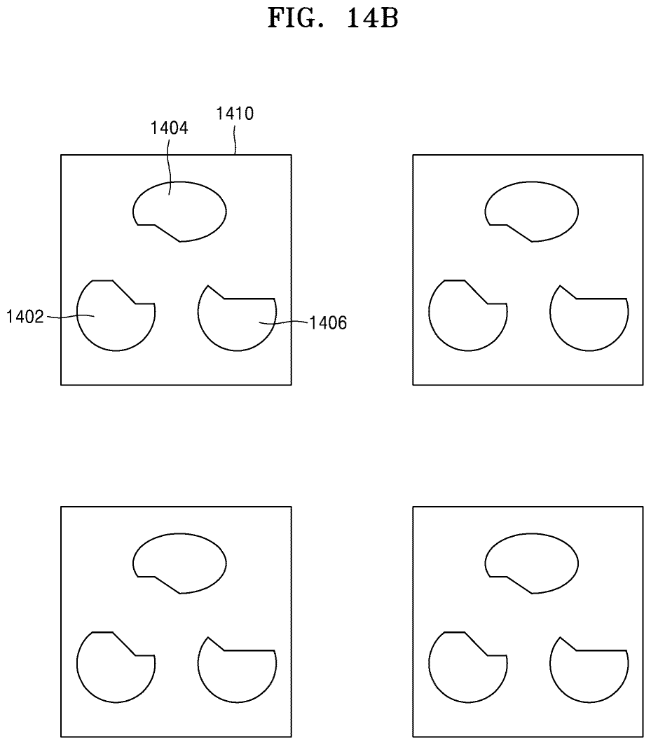

FIG. 14A shows a recessed portion of an interposer in which light-emitting elements are to be arranged, according to an embodiment.

According to an embodiment, the semiconductor device 100 may correspond to a light-emitting element. In some embodiments, the semiconductor device 100 may correspond to an LED chip used in a display device. As the light-emitting element having an asymmetric shape is arranged on the substrate with distinguished top, bottom, left, and right for arrangement thereof on the interposer, electrical bonding may be possible in a corresponding manner when the electrode of the device is connected to the substrate. Moreover, the light-emitting element may include a plurality of types of light-emitting elements 1402, 1404, and 1406 that output different color components. In some embodiments, the light-emitting elements 1402, 1404, and 1406 may include a first light-emitting element 1402 that outputs a first color component, a second light-emitting element 1404 that outputs a second color component, and a third light-emitting element 1406 that outputs a third color component. According to an embodiment, the first color component may be red, the second color component may be green, and the third color component may be blue. Combinations of the first color component, the second color component, and the third color component may vary with an embodiment.

According to an embodiment, the first light-emitting element 1402, the second light-emitting element 1404, and the third light-emitting element 1406 may have asymmetric shapes of different types. In some embodiments, the first light-emitting element 1402 may have the third asymmetric shape 1102, the second light-emitting element 1404 may have the fourth asymmetric shape 1202, and the third light-emitting element 1406 may have the fifth asymmetric shape 1302.

According to an embodiment, the first light-emitting element 1402, the second light-emitting element 1404, and the third light-emitting element 1406 may have different asymmetric shapes without being included in one another. In case that one asymmetric shape is included in another asymmetric shape, when the semiconductor device 100 is transferred to the interposer, to a recessed portion corresponding to a light-emitting element of a selected type, a light-emitting element of another type may be erroneously transferred. In some embodiments, assuming that the asymmetric shape of the first light-emitting element 1402 is included in the asymmetric shape of the second light-emitting element 1404, the first light-emitting element 1402 may be transferred to the recessed portion corresponding to the second light-emitting element 1404 as well as the recessed portion corresponding to the first light-emitting element 1402. According to an embodiment, as the asymmetric shapes of the first light-emitting element 1402, the second light-emitting element 1404, and the third light-emitting element 1406 are not included in one another, it is possible to erroneously transfer the light-emitting element of another type to the recessed portion of the interposer.

FIG. 14B shows arrangement of a recessed portion of an interposer according to an embodiment.

According to an embodiment, the recessed portion may be arranged as shown in FIG. 14B. One pixel 1410 may include the first light-emitting element 1402, the second light-emitting element 1404, and the third light-emitting element 1406 arranged as shown in FIG. 14B. The first light-emitting element 1402, the second light-emitting element 1404, and the third light-emitting element 1406 may be arranged such that their centers form a triangle.

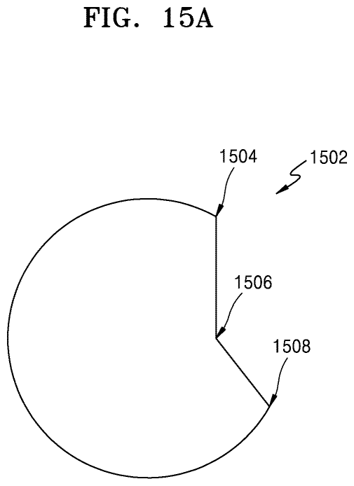

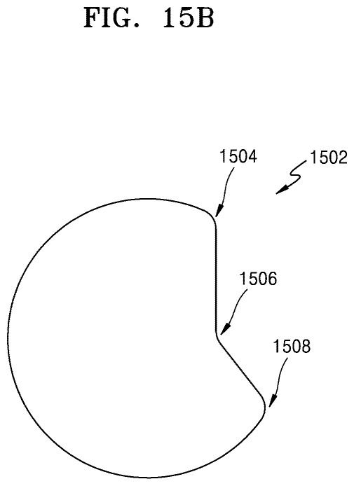

FIG. 15A shows a sixth asymmetric shape of a semiconductor device, according to an embodiment.

According to an embodiment, the semiconductor device 100 may have a sixth asymmetric shape 1502. The sixth asymmetric shape 1502 may have a shape in which a partial region is cut from a circle corresponding to a basic shape. The sixth asymmetric shape 1502 may include a curved section between a 51st point 1504 and a 53rd point 1508 and a linear section between the 51st point 1504 and the 53rd point 1508. The curved section between the 51st point 1504 and the 53rd point 1508 may correspond to a chord of a circle.

The linear section between the 51st point 1504 and the 53rd point 1508 may include two straight lines meeting each other at a 52nd point 1506. A length of the straight line between the 51st point 1504 and the 52nd point 1506 and a length of the straight line between the 52nd point 1506 and the 53rd point 1508 may be different from each other.

FIG. 15B shows deformation of a sixth asymmetric shape of a semiconductor device, according to an embodiment.

According to an embodiment, the semiconductor device 100 may be transformed such that vertices of the semiconductor device 100 have a round shape. In some embodiments, as shown in FIG. 15B, vertices of the 51st point 1504, the 52nd point 1506, and the 53rd point 1508 of the sixth asymmetric shape 1502 may be transformed to a round shape. By transforming the vertices into a round shape, entanglement in the semiconductor device 100 may be reduced.

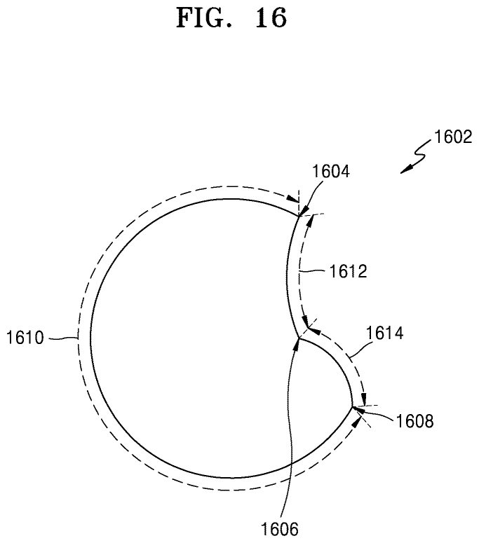

FIG. 16 shows a seventh asymmetric shape of a semiconductor device, according to an embodiment.

According to an embodiment, the semiconductor device 100 may have a seventh asymmetric shape 1602. The seventh asymmetric shape 1602 may have a shape in which a partial region is cut from a circle or an oval. The seventh asymmetric shape 1602 may include an 11th curved section 1610 between a 61st point 1604 and a 63rd point 1608, a 12th curved section 1612 between the 61st point 1604 and a 62nd point 1606, and a 13th curved section 1614 between the 62nd point 1606 and the 63rd point 1608. The 11th curved section 1610 may correspond to a chord of a circle or an oval. The 12th curved section 1612 may have a concave shape. The 13th curved section 1614 may have a convex shape. The 12th curved section 1612 and the 13th curved section 1614 may be formed to have different curvatures and lengths. According to an embodiment, the 12th curved section 1612 may have a longer length than the 13th curved section 1614. According to an embodiment, the 12th curved section 1612 may have a less curvature than the 13th curved section 1614. With such a structure, when a chip is arranged in a fluid self-assembly manner, entanglement between very small chips may be prevented, allowing each chip to be self-assembled with a recessed portion matching a pattern of the chip.

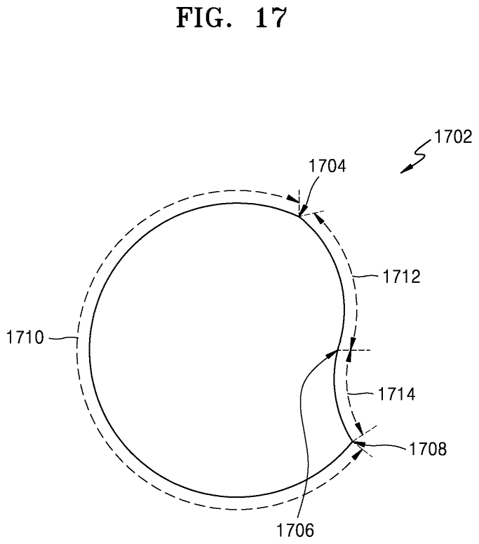

FIG. 17 shows an eighth asymmetric shape of a semiconductor device, according to an embodiment.

According to an embodiment, the semiconductor device 100 may have an eighth asymmetric shape 1702. The eighth asymmetric shape 1702 may have a shape in which a partial region is cut from a circle or an oval. The eighth asymmetric shape 1702 may include a 21st curved section 1710 between a 71st point 1704 and a 73rd point 1708, a 22nd curved section 1712 between the 71st point 1704 and the 73rd point 1708, and a 23rd curved section 1714 between the 72nd point 1706 and the 73rd point 1708. The 21st curved section 1710 may correspond to a chord of a circle or an oval. The 22nd curved section 1712 may have a convex shape. The 23rd curved section 1714 may have a concave shape. The 22nd curved section 1712 and the 23rd curved section 1714 may be formed to have different curvatures and lengths. According to an embodiment, the 22nd curved section 1712 may have a longer length than the 23rd curved section 1714. According to an embodiment, the 22nd curved section 1712 may have a less curvature than the 23rd curved section 1714.

According to an embodiment, the semiconductor device 100 having the sixth asymmetric shape 1502, the semiconductor device 100 having the seventh asymmetric shape 1602, and the semiconductor device 100 having the eighth asymmetric shape 1702 may correspond to light-emitting elements. In some embodiments, the semiconductor device 100 may correspond to an LED chip used in a display device. In some embodiments, the semiconductor device 100 having the sixth asymmetric shape 1502 may correspond to a first light-emitting element that outputs a first color component, the semiconductor device 100 having the seventh asymmetric shape 1602 may correspond to a second light-emitting element that outputs a second color component, and the semiconductor device 100 having the eighth asymmetric shape 1702 may correspond to a third light-emitting element that outputs a third color component.

According to an embodiment, the first color component may be red, the second color component may be green, and the third color component may be blue. Combinations of the first color component, the second color component, and the third color component may vary with an embodiment.

According to an embodiment, the semiconductor device 100 having the sixth asymmetric shape 1502, the semiconductor device 100 having the seventh asymmetric shape 1602, and the semiconductor device 100 having the eighth asymmetric shape 1702 may have different asymmetric shapes without being included in one another.

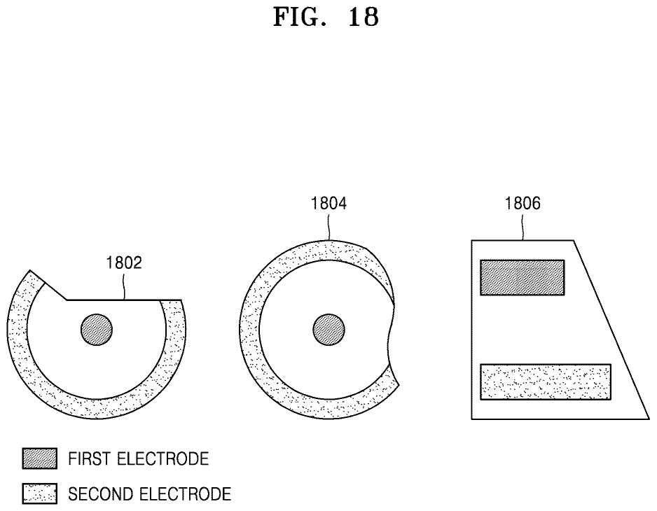

FIG. 18 shows light-emitting elements according to an embodiment.

At least one of a plurality of light-emitting elements 1802, 1804, and 1806 corresponding to different color components may include an asymmetric shape including a curved line, and at least one (of the plurality of light-emitting elements 1802, 1804, and 1806) may include an asymmetric shape defined as a straight line. In some embodiments, the first light-emitting element 1802 may correspond to the fifth asymmetric shape 1302, the second light-emitting element 1804 may have the eighth asymmetric shape 1702, and the third light-emitting element 1806 may have an asymmetric shape including a straight line.

According to an embodiment, each of the light-emitting elements 1802, 1804, and 1806 may include a plurality of electrodes. In some embodiments, the first light-emitting element 1802 and the second light-emitting element 1804 may include a first electrode in a center thereof and a second electrode in a rim thereof. The third light-emitting element 1806 may include a first electrode on a top portion thereof and a second electrode on a bottom portion thereof.

According to an embodiment, vertices of an asymmetric shape formed of straight lines like the third light-emitting element 1806 may be transformed into a round shape.

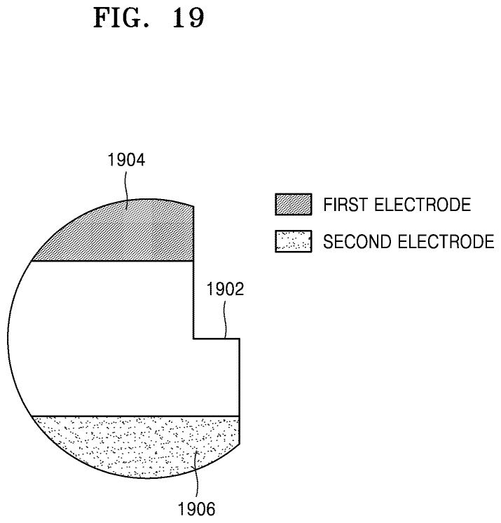

FIG. 19 shows electrode arrangement of a semiconductor device, according to an embodiment.

According to an embodiment, the semiconductor device 100 may have a ninth asymmetric shape. The ninth asymmetric shape may include a curved section and a linear section. The semiconductor device 100 having the ninth asymmetric shape may include a first electrode arranged in a first region 1904 adjacent to the curved section and the linear section and a second electrode arranged in a second region 1906 arranged on another end of the first region 1906.

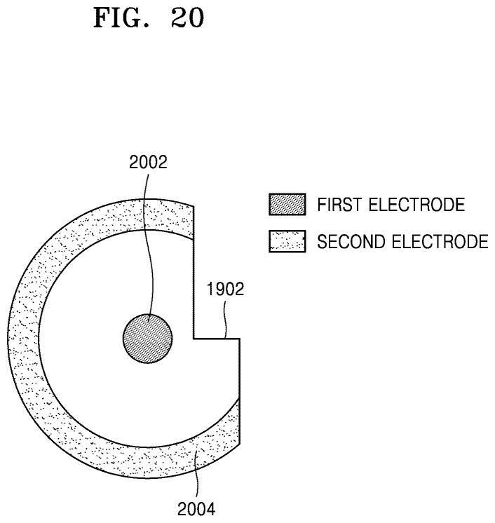

FIG. 20 shows electrode arrangement of a semiconductor device, according to an embodiment.

According to an embodiment, the semiconductor device 100 may have the ninth asymmetric shape. The ninth asymmetric shape may include a curved section and a linear section. The semiconductor device 100 may include a first electrode arranged in a center region 2002 of the ninth asymmetric shape and a second electrode arranged in a rim region 2004 of the ninth asymmetric shape. A process of forming an electrode may follow the manner described with reference to FIG. 7.

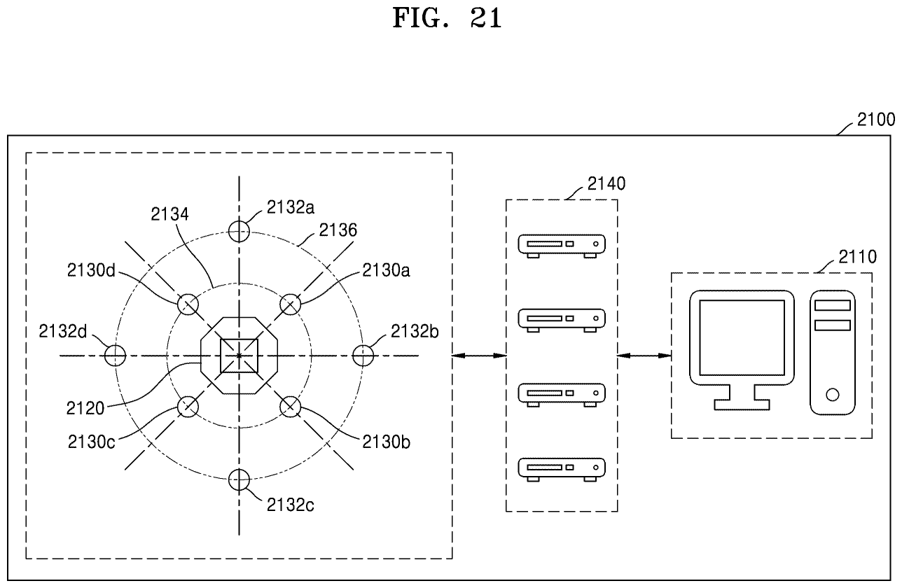

FIG. 21 shows a structure of a device transfer apparatus according to an embodiment.

According to an embodiment, by using fluid self-assembly, the semiconductor device 100 may be transferred to the interposer. According to an embodiment, by controlling the behavior of the semiconductor device 100 using vibration energy, the semiconductor device 100 may be transferred to the interposer. The semiconductor device 100 may also be transferred directly to a glass substrate on which a circuit is configured. A device transfer apparatus 2100 may receive a fluid and the semiconductor device 100 in a container 2120 and output vibration energy from a vibration source to transfer the semiconductor device 100 to the interposer.

The device transfer apparatus 2100 according to an embodiment may include the container 2120 and a plurality of vibration sources 2130a, 2130b, 2130c, 2130d, 2132a, 2132b, 2132c, and 2132d. In the disclosure, the plurality of vibration sources 2130a, 2130b, 2130c, 2130d, 2132a, 2132b, 2132c, and 2132d will be collectively indicated by reference numeral 2130.

The plurality of vibration sources 2130 may be connected to the container 2120 through a selected connection plate. The plurality of vibration sources 2130 may output vibration of a selected frequency, and the vibration output from the vibration source 2130 may be transmitted to the container 2120 through the connection plate.

The plurality of vibration sources 2130 may be controlled by a computing device 2110 including a processor. The computing device 2110 may output a control signal to the plurality of vibration sources 2130 to control at least one of on/off, output frequency, phase, timing, or vibration strength of the plurality of vibration sources 2130. The computing device 2110 may determine the output frequency of the plurality of vibration sources 2130 by using a selected computer program and data and control the plurality of vibration sources 2130 to output the output frequency determined by the plurality of vibration sources 2130.

The plurality of vibration sources 2130 may generate and output vibration based on a signal output from a signal amplifier 2140. The signal amplifier 2140 may generate and output a waveform signal corresponding to the output frequency by using the control signal output from the computing device 2110. The plurality of vibration sources 2130 may receive the waveform signal corresponding to the output frequency from the signal amplifier 2140 and generate and output vibration corresponding to the output frequency.

The container 2120 may have a polygonal shape. The container 210 may have, for example, an octagonal shape. The container 2120 may have, for example, a regular polygonal shape or a regular octagonal shape.

The container 2120 may have a fluid accommodation structure capable of accommodating a fluid. The fluid accommodation structure may be implemented in the form of a partition wall forming a space accommodating the fluid on a top surface of the container 2120. The fluid accommodation structure may correspond to a chunk. The fluid may correspond to, for example, ethanol. The interposer may be arranged in the container 2120.

According to an embodiment, the plurality of vibration sources 2130 may be arranged on a plurality of concentric circles 2134 and 2136. The number of concentric circles 2130 may be determined variously according to an embodiment. According to an embodiment, the plurality of concentric circles 2130 may include a first circle 2134 and a second circle 2136. The first circle 2134 may have a radius less than that of the second circle 2136. The plurality of vibration sources 2130 may be arranged to respectively correspond to surfaces of the container 2120 having a polygonal shape. In some embodiments, the container 2120 may have a regular octagonal shape, and eight vibration sources 2130 may be arranged to respectively correspond to surfaces of a regular octagon. The container 2120 may be arranged in the center of the plurality of concentric circles 2130.

The plurality of vibration sources 2130 may include first group vibration sources 2130a, 2130b, 2130c, and 2130d arranged on the first circle 2134 and second group vibration sources 2132a, 2132b, 2132c, and 2132d arranged on the second circle 2136. The first group vibration sources 2130a, 2130b, 2130c, and 2130d may include a plurality of vibration sources arranged on the first circle 2134. The second group vibration sources 2132a, 2132b, 2132c, and 2132d may include a plurality of vibration sources arranged on the second circle 2136.

The computing device 2110 may control vibration of a selected output frequency to be output through one or a combination of the first group vibration sources 2130a, 2130b, 2130c, and 2130d and the second group vibration sources 2132a, 2132b, 2132c, and 2132d. The computing device 2110 may determine the output frequency of the first group vibration sources 2130a, 2130b, 2130c, and 2130d or the second group vibration sources 2132a, 2132b, 2132c, and 2132d to move the semiconductor device 100 in a desired direction or pattern, and output vibration of the determined output frequency through at least one of the first group vibration sources 2130a, 2130b, 2130c, and 2130d or at least one of the second group vibration sources 2132a, 2132b, 2132c, and 2132d.

By outputting vibration of the output frequency through the first group vibration sources 2130a, 2130b, 2130c, and 2130d and the second group vibration sources 2132a, 2132b, 2132c, and 2132d, the vibration output from the plurality of vibration sources 2130 may be transmitted to the container 2120 through a connection plate and to the fluid in the container 2120. As the vibration is transmitted to the fluid, the semiconductor device 100 in the fluid may move in a selected direction or pattern by the vibration. The semiconductor device 100 may be distributed along a nodal line of a wave generated in the fluid by the vibration. In the disclosure, the vibration may be applied along each surface of the container 2120 having a polygonal shape. Through a combination of such vibration, the semiconductor device 100 may be distributed in a desired pattern in the fluid. Thus, the device transfer apparatus 2100 according to an embodiment may finely control movement of a micro element through a combination of vibration output through the plurality of vibration sources 2130.

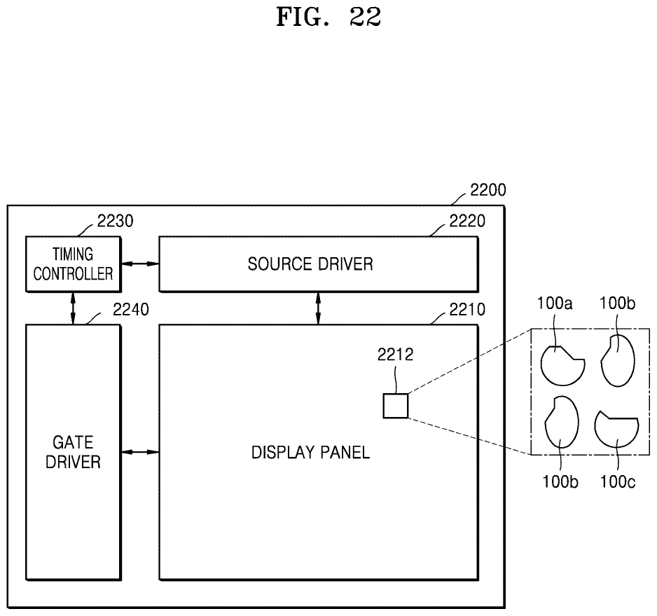

FIG. 22 shows a display device according to an embodiment.

A display device 2200, which is a device that configures a screen according to an image signal, may include a display panel 2210, a source driver 2220, a gate driver 2240, and a timing controller 2230. Such components may be arranged in a common substrate or module in the form of a box.

The display panel 2210 may include a plurality of pixels 2212. The pixels 2212 may be arranged in a two-dimensional (2D) array. Each pixel 2212 may include rows and columns and may be selected and driven by the source driver 2220 and the gate driver 2240. The display panel 2210 may be implemented with, for example, a liquid crystal display (LCD), an organic light-emitting (OLED) panel, etc.

The source driver 2220 may output a source driving signal of each pixel 2212 based on a data signal received from the timing controller 2230. The source driver 2220 may be arranged in a column direction of the display panel 2210, and may apply voltage to a pixel electrode to emit light of a desired gradation from the pixel 2212.

The gate driver 2240 may apply a scan signal to a gate line of a row selected according to a control signal of the timing controller 2230. In this way, the pixels 2212 of a specific row may be activated to receive a signal input from the source driver 2220 at a corresponding point in time. The gate driver 2240 may be arranged to correspond to the row direction of the display panel 2210.

The timing controller 2230 may be in charge of synchronization of the entire display device 2220 and generate and transmit a timing signal and a control signal required for the gate driver 2240 and the source driver 2220. The timing controller 2230 may adjust a scanning order of an image frame and maintain consistency of a data flow, thereby enabling high-quality stable screen output.

The pixel 2212, which is a display unit, may include a plurality of sub-pixels. The plurality of sub-pixels may include, for example, red (R), green (G), or blue (B). Respective sub pixels may be driven independently of each other and emit or transmit light of different intensities, such that a color expressed in the entire pixel 2212 may be determined. Through a combination of such sub pixels, the display device 2200 may implement an image of various colors.

According to an embodiment, each sub pixel may include light-emitting elements 100a, 100b, and 100c according to an embodiment. The plurality of sub pixels included in one pixel 2212 may include a combination of sub pixels of a plurality of color components. In some embodiments, the plurality of sub pixels may include a first sub pixel of a first color component, a second sub pixel of a second color component, and a third sub pixel of a third color component. The first sub pixel may include the first light-emitting element 100a, the second sub pixel may include the second light-emitting element 100b, and the third sub pixel may include the third light-emitting element 100c. The first light-emitting element 100a, the second light-emitting element 100b, and the third light-emitting element 100c may have different asymmetric shapes. The first light-emitting element 100a, the second light-emitting element 100b, and the third light-emitting element 100c may have different asymmetric shapes having types and sizes that do not completely include each other.

The disclosed embodiments have been described with reference to the attached drawings so far. Those of ordinary skill in the art will appreciate that the disclosure will be practiced in forms different from the disclosed embodiments without changing the technical spirit or essential characteristics of the disclosure. The disclosed embodiments are illustrative and should not be construed as limiting.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure as defined by the following claims.

What is claimed is:

1. A semiconductor device comprising:
an epitaxial layer; and
at least one electrode formed on the epitaxial layer,
wherein the epitaxial layer has an asymmetric shape including at least a partial curved section.

2. The semiconductor device of claim 1, wherein
the asymmetric shape includes a shape in which a partial region is removed from a basic shape of a circular shape or an elliptical shape.

3. The semiconductor device of claim 2, wherein
the asymmetric shape includes a shape comprising a linear edge of a portion in which a partial region is removed from a basic shape of a circular shape or an elliptical shape.

4. The semiconductor device of claim 2, wherein
the asymmetric shape includes a shape comprising a curved edge of a portion in which a partial region is removed from a basic shape of a circular shape or an elliptical shape.

5. The semiconductor device of claim 1, wherein
the asymmetric shape is asymmetric in each of a top-down direction, a left-right direction, and a front-back direction.

6. The semiconductor device of claim 1, wherein
the semiconductor device comprises a light-emitting element,
the semiconductor device comprises a first light-emitting element outputting a first color component, a second light-emitting element outputting a second color component, and a third light-emitting element outputting a third color component, and
the first light-emitting element, the second light-emitting element, and the third light-emitting element have asymmetric shapes of different types.

7. The semiconductor device of claim 6, wherein
the first light-emitting element, the second light-emitting element, and the third light-emitting element have asymmetric shapes of types and sizes that do not completely include each other.

8. The semiconductor device of claim 6, wherein
the semiconductor device comprises a light-emitting diode (LED) chip.

9. The semiconductor device of claim 1, wherein
the semiconductor device is formed by patterning the epitaxial layer formed on a silicon wafer into the asymmetric shape through photolithography and separating the semiconductor device from the silicon wafer.

10. The semiconductor device of claim 1, wherein
the semiconductor device has a size of about 10 μm to about 100 μm.

11. The semiconductor device of claim 1, wherein
the asymmetric shape includes a first linear section formed in a first direction, a second linear section formed in a first direction and parallel with the first linear section, a third linear section connecting an end of the first linear section to an end of the second linear section, and a curved section connecting another end of the first linear section to another end of the second linear section.

12. The semiconductor device of claim 11, wherein
the curved section corresponds to a chord of a circle or an oval.

13. The semiconductor device of claim 1, wherein
the asymmetric shape includes a curved section corresponding to a chord of a circle or an oval and a linear section connecting opposite ends of the chord and comprising at least one bent portion.

14. The semiconductor device of claim 1, wherein
the asymmetric shape includes a curved section corresponding to a chord of a circle or an oval and at least one concave section and at least one convex section connecting opposite ends of the chord.

15. The semiconductor device of claim 1, wherein
the semiconductor device is transferred to a recessed portion of an interposer, and the recessed portion has a shape that is identical to the asymmetric shape of the semiconductor device and is formed to have a selected gap with respect to an exterior of the semiconductor device such that the semiconductor device is accommodated.

16. The semiconductor device of claim 15, wherein
the semiconductor device is transferred to the interposer through movement by vibration in a fluid.

17. The semiconductor device of claim 1, wherein
the epitaxial layer comprises a plurality of layers comprising a GaN-based material.

18. A device transfer apparatus comprising:
a container accommodating an interposer comprising a plurality of recesses;
a plurality of vibration sources configured to generate vibrations and output the vibrations to a fluid in the container; and
a processor configured to control an output of each of the plurality of vibration sources,
wherein the container accommodates the fluid and a semiconductor device distributed in the fluid,
the processor is further configured to output vibrations from at least one of the plurality of vibration sources and transfer the semiconductor device to a plurality of recesses of the interposer,
the semiconductor device comprises an epitaxial layer and at least one electrode formed on the epitaxial layer,
the epitaxial layer has an asymmetric shape including at least a partial curved section, and
each of the plurality of recesses has a shape that is identical to an asymmetric shape of the semiconductor device and is formed to have a selected gap with respect to an exterior of the semiconductor device such that the semiconductor device is accommodated.

19. A display device comprising:
a display panel comprising a plurality of first light-emitting elements outputting a first color component, a plurality of second light-emitting elements outputting a second color component, and a plurality of third light-emitting elements outputting a third color component; and
a driving circuit configured to drive the display panel,
wherein each of the plurality of first light-emitting elements, the plurality of second light-emitting elements, and the plurality of third light-emitting elements comprises:
an epitaxial layer; and
at least one electrode formed on the epitaxial layer,
wherein the epitaxial layer has an asymmetric shape including at least a partial curved section, and
the first light-emitting element, the second light-emitting element, and the third light-emitting element have asymmetric shapes of different types.

20. The display device of claim 19, wherein
the first light-emitting element, the second light-emitting element, and the third light-emitting element have asymmetric shapes of types and sizes that do not completely include each other.
